(19) United States
(12) Patent Application Publication
(10) Pub. No.: US 2002/0024066 A1
(43) Pub. Date: Feb. 28, 2002

(54) Solid-state image pickup device

(75) Inventor: Takeshi Ide, Kanagawa (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 09/939,365

(22) Filed: Aug. 24, 2001

(30) Foreign Application Priority Data
Aug. 28, 2000 (JP) P2000-257464

(51) Int. Cl. H01L 29/76

(52) U.S. Cl. 257/214

(57) ABSTRACT

A solid-state image pickup device includes pixels disposed in a matrix manner; vertical-transfer registers for transferring accumulated signal electric charges, provided for pixel columns; and shunt wires connected to transfer electrodes of the vertical-transfer registers, extending so as to intersect with the vertical-transfer registers, and connected to bus lines outside an image pickup area.

### BACKGROUND OF THE INVENTION

1. Field of the Invention

The present invention relates to solid-state image pickup devices in which shunt wires are connected to transfer registers.

2. Description of the Related Art

To suppress the propagation delay of a vertical-transfer clock, shunt wires are provided for solid-state image pickup devices, such as those having a pickup size of ⅔ inches or more, those having a high frame rate, such as those in the HD/SD specifications (1/30 seconds and 1/60 seconds), and CCD solid-state image pickup devices having an FIT structure in which a high-speed frame shift operation is performed.

Solid-state image pickup devices having shunt wires have a basic structure in which shunt bus lines are disposed at the opposite side of a horizontal transfer register against an image pickup area, and shunt wires are extended from the bus lines in parallel to pixel columns, so that a shunt wire is provided for each pixel column.

FIG. 4 is a general structural view (plan) of a CCD solid-state image pickup device having conventional shunt wires.

In this CCD solid-state image pickup device 51, a vertical-transfer register 53 extending in the vertical direction is provided for each column of pixels (see FIG. 5) formed of sensors, disposed in a matrix manner in an image pickup area 52. A horizontal-transfer register 56 is disposed at a lower part in the figure in the image pickup area 52 and is connected to an end of each vertical-transfer register 53. The horizontal-transfer register 56 is connected to an output buffer 57.

As indicated by arrows in the figure, signal electric charges are transferred in the lower direction in the vertical-transfer registers 53 to the horizontal-transfer register 56. Then, the signal electric charges are transferred to the left in the horizontal-transfer register 56 and output through the output buffer 57.

At an upper part of the image pickup area 52 in the figure, bus lines 55 for shunt wires 54 are disposed. The shunt wires 54 are extended from the bus lines 55 in the lower direction in parallel to the vertical-transfer registers 53. The bus lines 55 include four wires B1, B2, B3, and B4 each having a rectangular loop shape. First-phase to fourth-phase driving pulses φV1, φV2, φV3, and φV4 are applied to the wires B1, B2, B3, and B4 of the bus lines 55, respectively.

The bus lines 55 are connected to transfer electrodes to which the driving pulses φV1, φV2, φV3, and φV4 are applied of the vertical-transfer registers 53 through the shunt wires 54.

The loop-shaped bus lines 55 are connected to the shunt wires 54 at an image-pickup 52 side (lower side) and are connected to pads 58 for applying the driving pulses φV1, φV2, φV3, and φV4 from the outside, at the opposite side (upper side).

FIG. 5 is an enlarged view of the image pickup area of the CCD solid-state image pickup device 52 shown in FIG. 4.

The shunt wires 54 are connected to transfer electrodes 61 (61A and 61B) made from polycrystalline silicon through buffer wires (buffering wires) 62 made from polycrystalline silicon.

The buffer wires 62 are disposed between the shunt wires 54 serving as an upper layer and the transfer electrodes 61 serving as a lower layer, and are extended in the vertical direction in parallel to the shunt wires 54 such that the shunt wires 54 are backed with the buffer wires 62.

The buffer wires 62 are electrically connected to predetermined transfer electrodes 61, namely, first-layer transfer electrodes 61A or second-layer transfer electrodes 61B, through contact sections 63, and are electrically connected to predetermined shunt wires 54 through contact sections 64.

The buffer wires 62 prevent a phenomenon in which the potentials of the channels of the vertical-transfer registers 53 change, which occurs when the transfer electrodes 61 are directly connected to the shunt wires 54.

When the shunt wires 54 are made from a high-melting-point metal, such as aluminum or tungsten, the resistance of wires used for transfer in the vertical-transfer registers 53 is made small to suppress the propagation delay of the vertical-transfer registers 53.

It is difficult for solid-state image pickup devices required in the future, such as CCD solid-state image pickup devices having many pixels, for example, 1,000 million pixels, and those having a screen for 35-mm lenses or larger, to suppress a propagation delay just by providing the above-described shunt wires 54 disposed vertically.

A very high horizontal-driving frequency is required to take out all signals from one output in image pickup devices having many pixels, but it is technically impossible to implement.

A method can be considered in which a screen (image pickup area) is divided, and signals are taken out from division outputs (multi-channel outputs) to reduce the driving frequency.

In the structure of the currently used shunt wires 54 disposed vertically, however, since the bus lines 55 are disposed at the upper side of the image pickup area 52 in the figure, as shown in FIG. 4, the horizontal-transfer register 56 cannot be provided anywhere other than the lower side of the image pickup area 52 in the figure.

Therefore, a screen division is limited to a case in which the image pickup area is divided into two left and right regions 52L and 52R, as shown in FIG. 6.

In this case, the horizontal-transfer register 56 is divided into two right and left regions to form two horizontal-transfer registers 56L and 56R, and output buffers 57L and 57R are provided therefor to output signals in the right and left directions. The bus lines 55 are provided for each of the two regions 52L and 52R, and are connected to the shunt wires 54 in each of the two regions 52L and 52R.

Therefore, more than two outputs cannot be obtained, and the driving frequency is divided to about a half at most.

### SUMMARY OF THE INVENTION

The present invention has been made in consideration of the foregoing condition. Accordingly, it is an object of the present invention to provide a solid-state image pickup device having many pixels or a large screen by suppressing a propagation delay and reducing the driving frequency.

The foregoing object is achieved by the present invention through the provision of a solid-state image pickup device including pixels disposed in a matrix manner; vertical-transfer registers for transferring accumulated signal electric charges, provided for pixel columns; and shunt wires connected to transfer electrodes of the vertical-transfer registers, wherein the shunt wires extend so as to intersect with the vertical-transfer registers and are connected to bus lines outside an image pickup area.

In the solid-state image pickup device, the shunt wires may be disposed above the regions sandwiched by the pixels.

The solid-state image pickup device may be configured such that the vertical-transfer registers are divided into two portions, and horizontal-transfer registers are provided for the two portions, respectively, and are connected to ends thereof.

According to the present invention, since the shunt wires extend so as to intersect with the vertical-transfer registers, the bus lines connected to the shunt wires can be disposed at positions other than those for the horizontal-transfer registers connected to ends of the vertical-transfer registers.

Therefore, for example, the horizontal-transfer registers can be disposed above and below the image pickup area, and the bus lines can be disposed at the right and left of the image pickup area. Output channels can be increased as compared with a conventional case in which a horizontal-transfer register is disposed at one side of the image pickup area.

Consequently, according to the present invention, the shunt wires suppress a propagation delay, and output channels are increased to reduce the driving frequency, thereby allowing a solid-state image pickup device to have many pixels or a large screen.

When the shunt wires are disposed above the regions sandwiched by the pixels, since no shunt wire is disposed at the sides of the pixels, a shielding film formed above the shunt wires are made low, thereby increasing the sensitivity of the image pickup device.

### BRIEF DESCRIPTION OF THE DRAWINGS

FIG. 1 is a general structural view (plan) of a solid-state image pickup device according to an embodiment of the present invention.

FIG. 2 is an enlarged view of the image pickup area of the solid-state image pickup device shown in FIG. 1.

FIG. 3 is a sectional view taken along A-A′ in FIG. 2.

FIG. 4 is a general structural view (plan) of a CCD solid-state image pickup device having conventional shunt wires.

FIG. 5 is an enlarged view of the image pickup area of the CCD solid-state image pickup device shown in FIG. 4.

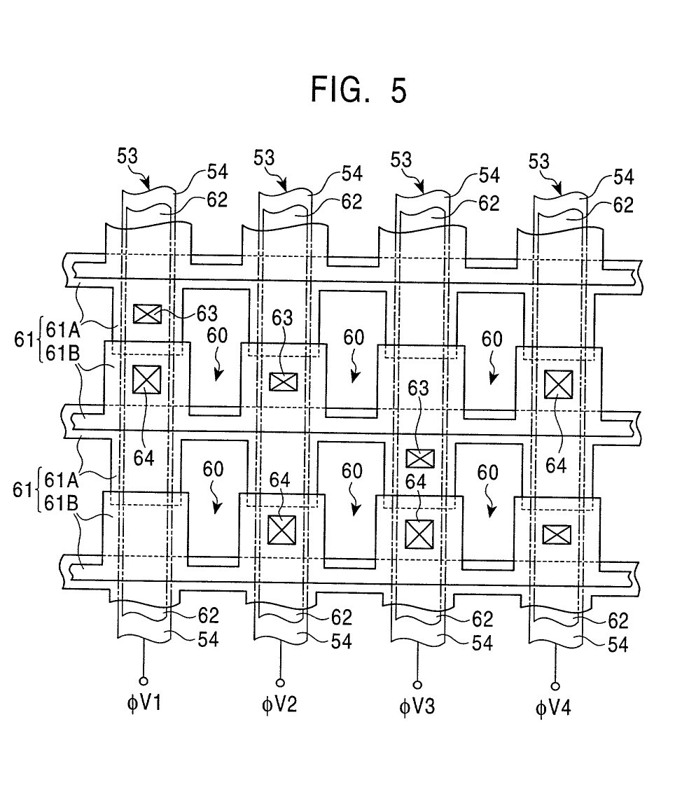

FIG. 6 is a general structural view (plan) of a CCD solid-state image pickup device having division outputs and a structure in which conventional shunt wires are provided.

### DESCRIPTION OF THE PREFERRED EMBODIMENT

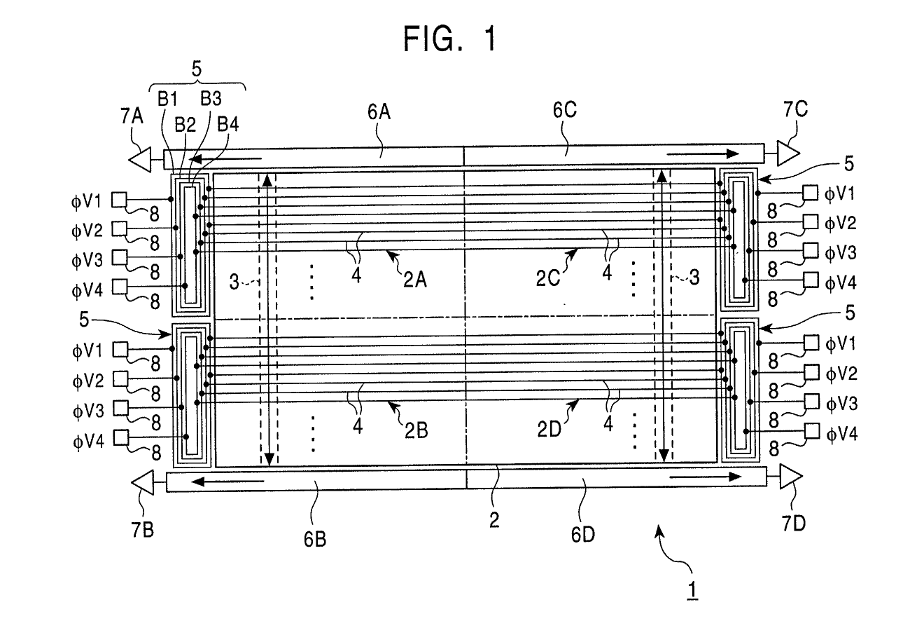

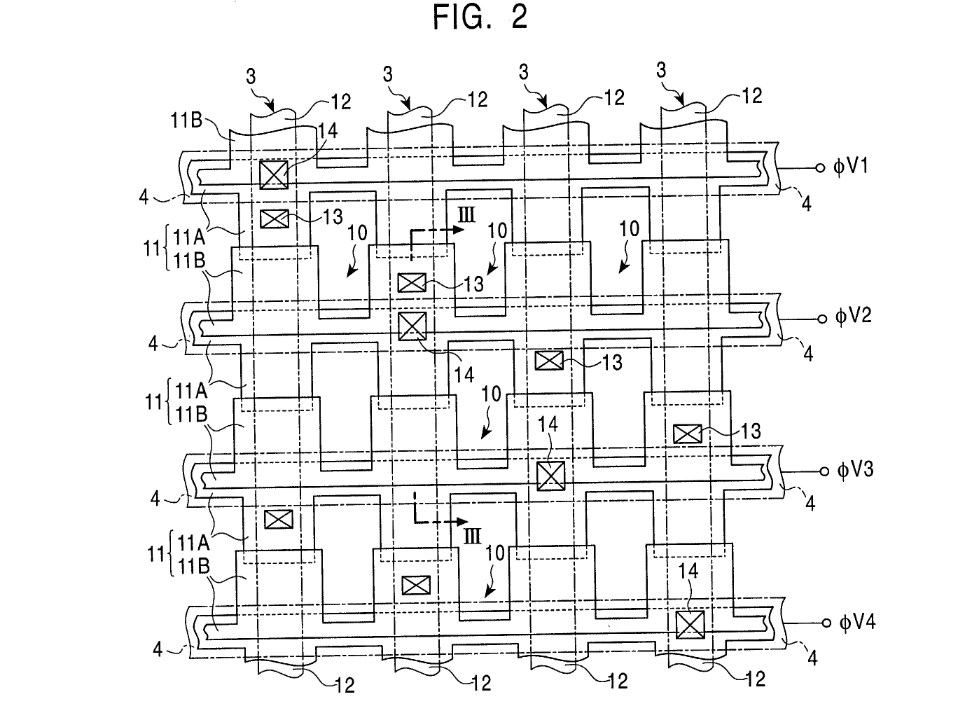

FIG. 1 is a general structural view (plan) of a solid-state image pickup device according to an embodiment of the present invention. FIG. 2 is an enlarged view of the image pickup area of the solid-state image pickup device shown in FIG. 1. In FIG. 1, sensors 10 which constitute pixels are not shown.

In this solid-state image pickup device 1, the pixels formed of the sensors 10 are disposed in a matrix manner, as shown in FIG. 2, and a vertical-transfer register 3 for transferring accumulated signal electric charges is provided for each column of pixels.

In the present embodiment, shunt wires 4 for suppressing the propagation delay of the vertical transfer registers 3 are extended in the horizontal direction in the figure so as to intersect with the vertical-transfer registers 3 disposed in the vertical direction in the figure.

The shunt wires 4 are made from a high-melting-point metal, such as aluminum or tungsten. with the shunt wires 4, the resistance of wires used for transfer in the vertical-transfer registers 3 is made small to suppress the propagation delay of the vertical-transfer registers 3.

Bus lines 5 for the shunt wires 4 are disposed outside the image pickup area 2 in the horizontal direction.

In the present embodiment, the image pickup area 2 is divided almost at its center into four portions, right and left, and up and low. The shunt wires 4 are also divided right and left, and the vertical-transfer registers 3 are divided up and low, accordingly.

The image pickup area 2 divided into the four portions is provided with the bus lines 5 for the shunt wires 4, horizontal-transfer registers 6A, 6B, 6C, and 6D, and output buffers 7A, 7B, 7C, and 7D.

In the two portions 2A and 2C disposed at the upper half of the image pickup area 2, signal electric charges are transferred in the upper direction in vertical-transfer registers 3 in the figure to the horizontal-transfer registers 6A and 6C disposed above the image pickup area 2. In contrast, in the two portions 2B and 2D disposed at the lower half of the image pickup area 2, signal electric charges are transferred in the lower direction in vertical-transfer registers 3 in the figure to the horizontal-transfer registers 6B and 6D disposed below the image pickup area 2.

Signal electric charges are transferred in the left direction in the figure in the horizontal-transfer registers 6A and 6B disposed at the left-hand side, and signal electric charges are transferred in the right direction in the figure in the horizontal-transfer registers 6C and 6D disposed at the right-hand side.

With these operations, signal electric charges sent to the horizontal-transfer registers 6A, 6B, 6C, and 6D are output through the output buffers 7A, 7B, 7C, and 7D.

Therefore, four-channel outputs are obtained.

The bus lines 5 for the shunt wires 4 are disposed at a total of four positions, two each at right and left positions, correspondingly to the four portions 2A, 2B, 2C, and 2D obtained by dividing the image pickup area 2, in the right-hand and left-hand sides outside the image pickup area 2.

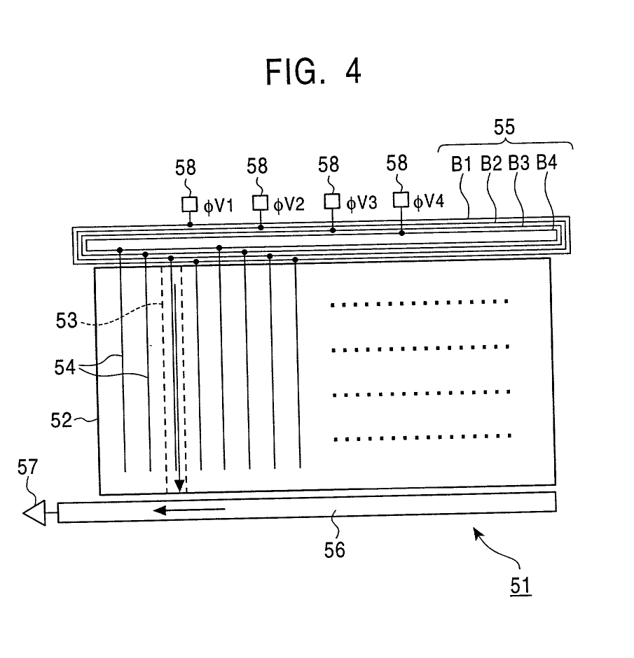

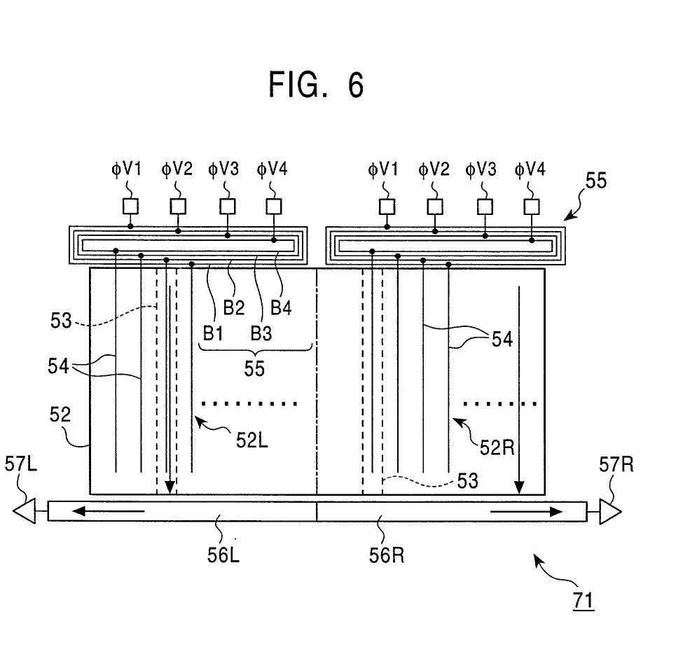

Each set of the bus lines 5 are formed of four rectangular loop-shaped wires B1, B2, B3, and B4 in the same way as shown in FIG. 4 and FIG. 6.

A first-phase driving pulse φV1 is applied to the outermost wire B1, a second-phase driving pulse φV2 is applied to the next inner wire B2, a third-phase driving pulse φV3 is applied to the next inner wire B3, and a fourth-phase driving pulse φV4 is applied to the innermost wire B4. The wires B1, B2, B3, and B4 of the bus lines 5 are connected to transfer electrodes to which the driving pulses φV1, φV2, φV3, and φV4 are applied of the vertical-transfer registers 3 through shunt wires 4.

The loop-shaped bus lines 5 are connected to the shunt wires 4 at the image pickup area 2 side, and are connected to wires to pads 8, for applying the driving pulses φV1 to φV4 from the outside, at the other side.

As shown in FIG. 2, the shunt wires 4 extending in the horizontal direction are disposed so as to intersect with the vertical-transfer registers 3 and to pass between the sensors 10 of pixels adjacent in the vertical direction, so that the shunt wires do not overlap the sensors 10.

The shunt wires 4 are electrically connected to buffer wires (buffering wires) 12 made from a polycrystalline silicon layer. The buffer wires 12 extend in the vertical direction as the vertical-transfer registers 3.

The buffer wires 12 are electrically connected to predetermined transfer electrodes 11, namely, first-layer transfer electrodes 11A or second-layer transfer electrodes 11B, through contact sections 13.

With these connections, the shunt wires 4 are electrically connected to transfer electrodes 11 through the buffer wires 12.

When the shunt wires 4 are directly connected to transfer electrodes 11, the potentials of the channels of the vertical-transfer registers 3 may change. More specifically, when driving pulses are applied through the shunt wires 4, capacitive coupling is generated between the shunt wires 4 and transfer electrodes 11 which are not connected thereto to change the potential obtained below the transfer electrodes 11.

The buffer wires 12 prevent the potential from changing.

The first-phase driving pulse φV1 is applied to the first-layer transfer electrodes 11A, the second-phase driving pulse φV2 is applied to the second-layer transfer electrodes 11B, the third-phase driving pulse φV3 is applied to the first-layer transfer electrodes 11A, and the fourth-phase driving pulse φV4 is applied to the second-layer transfer electrodes 11B.

Therefore, four-phase transfer is performed in the vertical-transfer registers 3, including the transfer electrodes 11 (11A and 11B).

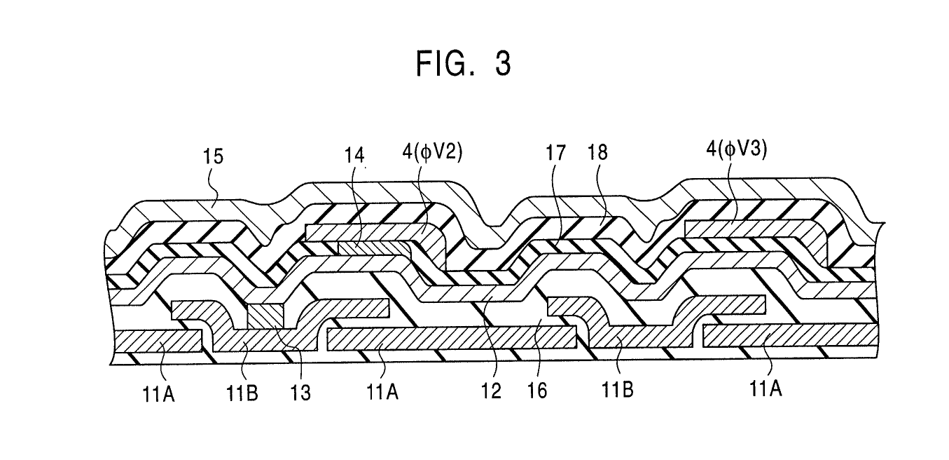

FIG. 3 is a sectional view taken along A-A′ in FIG. 2.

A buffer wire 12 is disposed above transfer electrodes 11A and 11B through an insulating film 16, and is connected to a predetermined transfer electrode 11 (to a second-layer transfer electrode 11B at the lower left in the figure) through a contact section 13.

Shunt wires 4 are disposed above the buffer wire 12 through an insulating film 17. The buffer wire 12 is connected to a predetermined shunt wire 4 (at the left-hand side in the figure) through a contact section 14.

Above the shunt wires 4, a shielding film 15 formed of an aluminum film or a tungsten film is disposed through an insulating film 18. The shielding film 15 has openings (not shown) above sensors 10.

In the present embodiment, since the shunt wires 4 extend in the horizontal direction and pass between the sensors 10, the shunt wires 4 are disposed only partially in the vertical direction, as shown in FIG. 3.

Therefore, at portions where no shunt wire 4 is disposed, that is, at the sides of the sensors 10, the shielding film 15 is formed low, which is lower than in a conventional case in which shunt wires are formed in the vertical direction.

Consequently, when it is assumed that the areas of the openings disposed above the sensors 10 of the shielding film 15 are the same, since the shielding film 15 is formed lower, light incident on the sensors 10 at angles increases, and sensitivity is improved.

In the present embodiment, the bus lines 5 have a rectangular loop-shape. The shape is not limited to a loop shape. They may have other shapes if the shunt wires 4 and the wires for the pads 8 can contact the bus lines 5 without difficulty.

According to the present embodiment, since the shunt wires 4 extend in the horizontal direction to intersect with the vertical-transfer registers 3, the bus lines 5 for the shunt wires 4 can be disposed at the right-hand and left-hand sides of the image pickup area 2. In other words, they can be disposed at positions other than those for the horizontal-transfer registers 6A, 6B, 6C, and 6D connected to ends of the vertical-transfer registers 3.

Therefore, the horizontal-transfer registers 6A, 6B, 6C, and 6D can be disposed not only below the image pickup area 2 but above it.

Consequently, it is possible that the image pickup area 2 is divided into upper and lower portions, and the horizontal-transfer registers 6A and 6C, and 6B and 6D are disposed above and below the image pickup area 2 to output signals.

In the present embodiment, the image pickup area 2 is further divided into the right-hand and left-hand portions to obtain a total of four divisions, and the portions 2A, 2B, 2C, and 2D obtained by dividing the image pickup area 2 into four are provided with the horizontal-transfer registers 6A, 6B, 6C, and 6D, and the output buffers 7A, 7B, 7C, and 7D. Therefore, four-channel outputs are obtained.

Consequently, the driving frequency is much reduced to about one fourth.

In addition, since the shunt wires 4 extending in the horizontal direction are disposed between the sensors 10 in the vertical direction, no shunt wire 4 is disposed at the sides of the sensors 10. Therefore, the shielding film 15 disposed above the shunt wires 4 is made low at the sides of the sensors 10.

Consequently, since the shielding film 15 is formed at the sides of the sensors 10 lower than in the conventional case in which the shunt wires are formed in the vertical direction, light incident on the sensors 10 at angles is increased to improve sensitivity.

The present invention is not limited to the above-described embodiment. Various structures can be used within the scope of the present invention.

What is claimed is:

1. A solid-state image pickup device comprising:
pixels disposed in a matrix manner;
vertical-transfer registers for transferring accumulated signal electric charges, provided for pixel columns; and
shunt wires connected to transfer electrodes of the vertical-transfer registers,
wherein the shunt wires extend so as to intersect with the vertical-transfer registers and are connected to bus lines outside an image pickup area.

2. A solid-state image pickup device according to claim 1, wherein the shunt wires are disposed above the regions sandwiched by the pixels.

3. A solid-state image pickup device according to claim 1, wherein the vertical-transfer registers are divided into two portions, and horizontal-transfer registers are provided for the two portions, respectively, and are connected to ends thereof.
